(19) United States
(12) Patent Application Publication
(10) Pub. No.: US 2009/0223443 A1
(43) Pub. Date: Sep. 10, 2009

(54) SUPERCRITICAL FILM DEPOSITION APPARATUS

(75) Inventor: Hiroyuki Ode, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/395,779

(22) Filed: Mar. 2, 2009

(30) Foreign Application Priority Data
Mar. 4, 2008 (JP) 2008-053910

(51) Int. Cl. C23C 14/00

(52) U.S. Cl. 118/50

(57) ABSTRACT

A supercritical film deposition apparatus for depositing a film on a substrate under a supercritical fluid ambient by supplying a deposition source material, includes: an autoclave that includes a reactor for depositing the film; a load lock chamber that is provided in the autoclave wherein the substrates before and after suffering depositing the film are transferred to the load lock chamber; a pressure control unit that is provided in the load lock chamber to control a pressure in the load lock chamber; an external gateway that is provided in the load lock chamber to transfer the substrate from and to outside of the autoclave; an internal gateway that is provided in the load lock chamber to transfer the substrate from and to the reactor; and a partition capable of opening and closing so as to isolate the load lock chamber from outside of the internal gateway.

### BACKGROUND OF THE INVENTION

1. Field of the Invention

The present invention relates to a supercritical film deposition apparatus, which deposits a film by supplying a source material on a substrate under a supercritical fluid ambient, and relates to a method of supercritical film deposition.

Priority is claimed on Japanese Patent Application No. 2008-53910, filed Mar. 4, 2008, the content of which is incorporated herein by reference.

2. Description of Related Art

Recently, in connection with down-sizing of a semiconductor device, a method of supercritical film deposition, in which a supercritical fluid is used as a medium material for film deposition, and a supercritical film deposition apparatus used for the method of supercritical film deposition have been developed (for example, refer to Japanese Unexamined Patent Application, First Application, No. 2003-213425, No. 2007-95863, No. 2007-162081, and No. 2007-250589). A supercritical condition is that temperature and pressure exceed an inherent value of a material (in other words, critical point), and the material is assumed to have both gaseous and fluid features.

An advantageous aspect of the method of supercritical film deposition against a conventional method of the film deposition such as a chemical vapor deposition (CVD) method, a physical vapor deposition (PVD) method and the like, is often considered that a deposition rate, or a film deposition reaction rate, of the supercritical film deposition is higher than that of the conventional method. However, in view of evaluation on a throughput for the total process of the supercritical film deposition, there is a problem in that it takes a considerably long time for a preliminary process, which is necessary before and after the film deposition (for example, pressurization to exceed the critical pressure, decompression to an atmospheric pressure, heating to a film deposition temperature), as compared with the conventional method of the film deposition under a vacuum condition.

In the case of the film deposition under the vacuum condition, in order to enhance the throughput, a wafer is generally replaced by using a load lock system. As for the supercritical film deposition apparatus, in order to enhance the throughput, a supercritical film deposition apparatus, which employs the load lock system for replacing the wafer under a high-pressure condition, has been developed

However, if a load lock chamber is provided in the supercritical film deposition apparatus, which uses the supercritical fluid with a high-pressure, to employ the load lock system, there are problems described hereinbelow.

FIG. 9 is a horizontal cross-sectional view that shows an example of the supercritical film deposition apparatus including the load lock chamber. The supercritical film deposition apparatus includes a reactor (film deposition chamber) 32, a transfer chamber 31, and a load lock chamber 30. As shown in FIG. 9, the transfer chamber 31 and the film deposition chamber 32 are connected by an aperture portion 3 la that passes a semiconductor wafer. A partition 33, which isolates the transfer chamber 31 and the film deposition chamber 32 from the load lock chamber 30, is provided between the transfer chamber 31 and the load lock chamber 30. An outer diameter of the partition 33 is larger than an inner diameter of an aperture portion 30a of the load lock chamber 30. The partition 33 is provided to cover the aperture portion 30a from a transfer chamber 31 side. The partition 33 can move toward the transfer chamber 31 side. A open/close mechanism 34 allows the partition 33 to open and close. As shown in FIG. 9, when the partition 33 is closed by the open/close mechanism 34, the load lock chamber 30 is completely isolated from the transfer chamber 31.

In the supercritical film deposition apparatus shown in FIG. 9, it is difficult to open and close the partition 33 when the wafer is replaced by using the load lock system under a supercritical fluid ambient with a high-pressure. For example, in the supercritical film deposition apparatus shown in FIG. 9, when a pressure in the load lock chamber 30 is lower than that in the transfer chamber 31, since the partition 33 is pressed to the aperture 30a of the load lock chamber 30 by the pressure in the transfer chamber 31, it is hard to move the partition 33. On the other hand, when the pressure in the load lock chamber 30 is higher than that in the transfer chamber 31, since the partition 33 is pushed toward a transfer chamber 31 direction, a movability of the partition 33 easily become unstable. For this reason, in the supercritical film deposition apparatus shown in FIG. 9, it is difficult to safely and easily open and close the partition 33. Furthermore, since it is difficult to safely and easily open and close the partition 33, an excess load is easily subjected to a mechanical part of the open/close mechanism 34 that supports the partition 33 and allows it to open and close. Therefore, durability of the partition 33 and the open/close mechanism 34 is insufficient in some cases.

In the supercritical film deposition apparatus shown in FIG. 9, there is a problem in that a deposition (reaction) condition in the film reposition chamber 32 is changed by thermal diffusion originated from a heat source for heating the wafer in the film deposition chamber 32. Furthermore, there is a problem in that since a temperature variation in the entire apparatus occurs with time, degradation and damage of each component are taken place.

### SUMMARY

The present invention seeks to solve one or more of the above problems, or to improve those problems at least in part

In one embodiment, there is provided a supercritical film deposition apparatus for depositing a film on a substrate under a supercritical fluid ambient by supplying a deposition source material, including: an autoclave that includes a reactor; a load lock chamber that is provided in the autoclave, the substrates before and after suffering depositing the film being transferred; a pressure control unit that is provided in the load lock chamber to control a pressure in the load lock chamber; an external gateway that is provided in the load lock chamber to transfer the substrate from and to outside of the autoclave; an internal gateway that is provided in the load lock chamber to transfer the substrate from and to the reactor; and a partition capable of opening and closing so as to isolate the load lock chamber from outside of the internal gateway.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a horizontal cross-sectional view that shows an example of a supercritical film deposition apparatus of the present invention;

FIG. 2A is a vertical cross-sectional view that shows a reactor (film deposition chamber) included in the supercritical film deposition apparatus shown in FIG. 1;

FIG. 2B is a vertical cross-sectional view that shows the reactor (film deposition chamber) included in the supercritical film deposition apparatus shown in FIG. 1;

FIG. 3A is a schematic diagram that shows a pipe line included in the supercritical film deposition apparatus shown in FIG. 1;

FIG. 3B is a schematic diagram that shows the pipe line included in the supercritical film deposition apparatus shown in FIG. 1;

FIG. 4A is a schematic diagram that shows the pipe line included in the supercritical film deposition apparatus shown in FIG. 1;

FIG. 4B is a schematic diagram that shows the pipe line included in the supercritical film deposition apparatus shown in FIG. 1;

FIG. 5 is a vertical cross-sectional view that shows a load lock chamber and a transfer chamber included in the supercritical film deposition apparatus shown in FIG. 1;

FIG. 6 is a perspective view that shows a partition included in the supercritical film deposition apparatus shown in FIG. 1;

FIG. 7 is a horizontal cross-sectional view that shows the supercritical film deposition apparatus, in which the partition is opened;

FIG. 8 is a vertical cross-sectional view that shows another example of the supercritical film deposition apparatus of the present invention; and

FIG. 9 is a horizontal cross-sectional view that shows an example of a supercritical film deposition apparatus including the load lock chamber.

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated here for explanatory purposes.

A first embodiment of a supercritical film deposition apparatus and a method of supercritical film deposition of the present invention will be described in detail hereinbelow with reference to the drawings. Although carbon dioxide (CO₂) is used as a specific supercritical fluid in the embodiment described below, the other supercritical fluid may be employed. For the sake of understanding a feature of the embodiment easily, there is a case that magnifies important parts for convenience in the drawings. Therefore, each component is not always shown at scale in accord with an actual case.

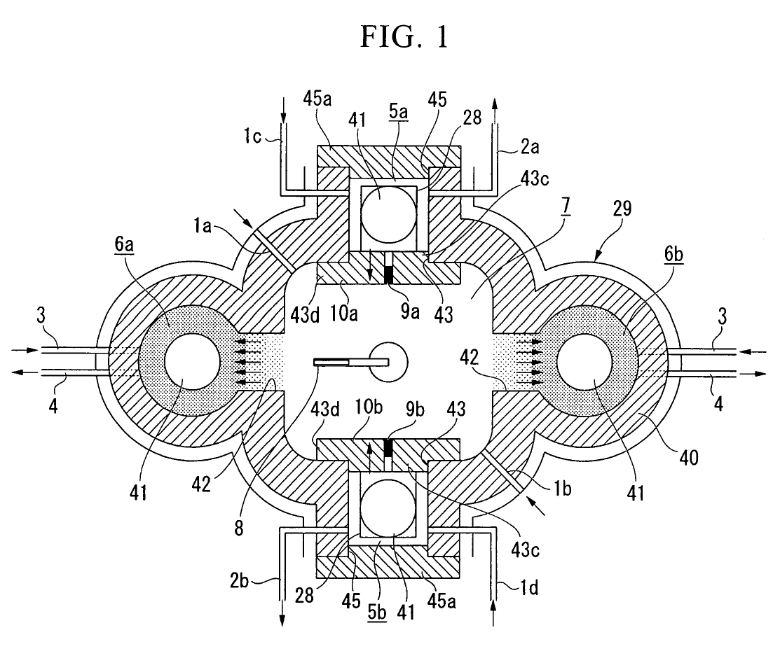

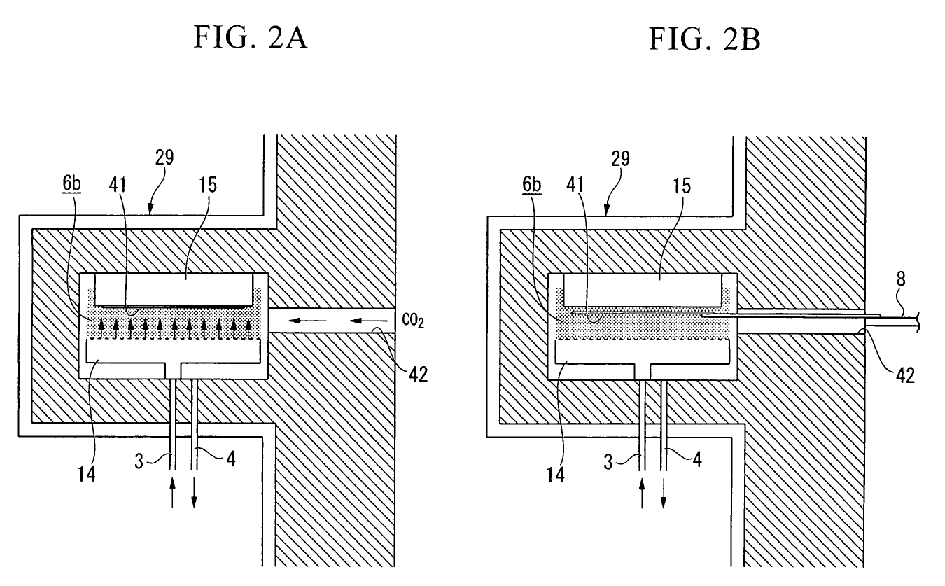

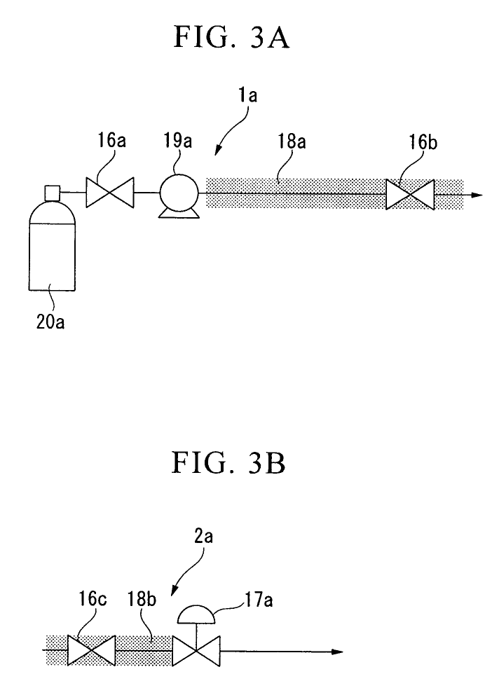

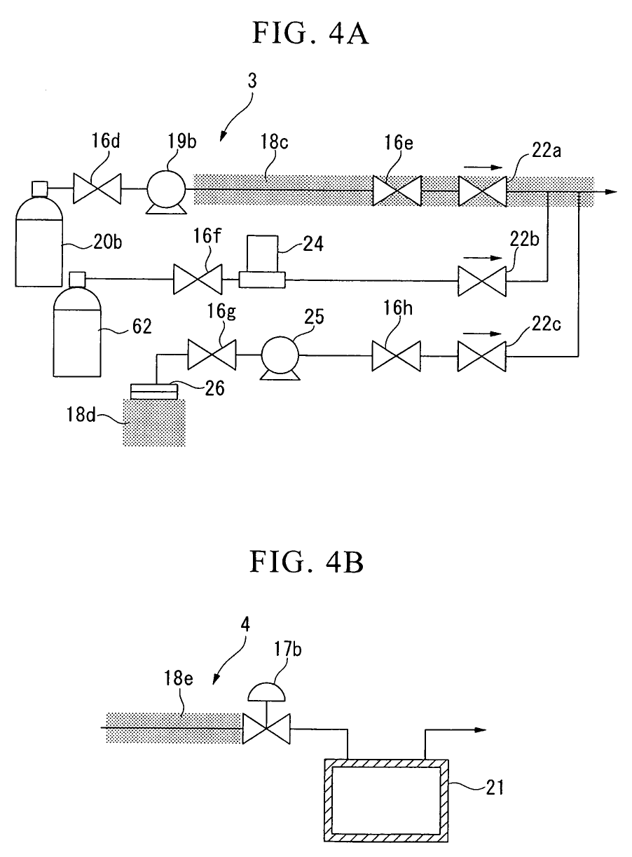

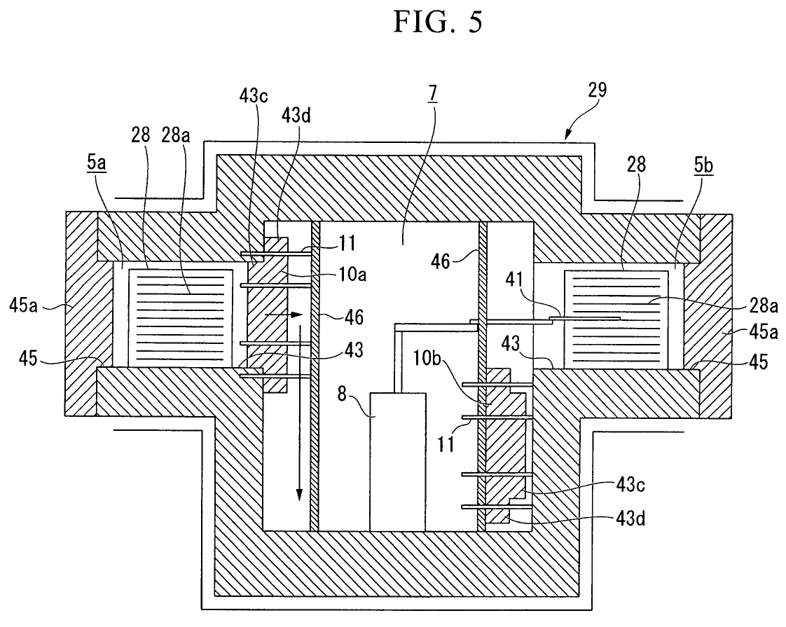

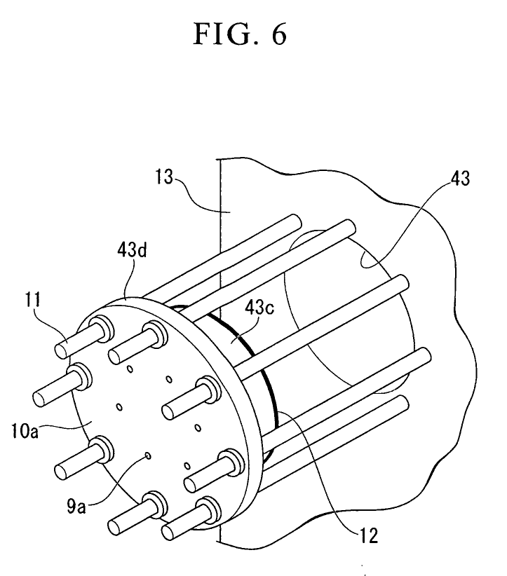

FIG. 1 is a horizontal cross-sectional view that shows an example of the supercritical film deposition apparatus of the present invention. FIG. 2A and FIG. 2B are vertical cross-sectional views that show a reactor (film deposition chamber) included in the supercritical film deposition apparatus shown in FIG. 1. FIG. 3A to FIG. 4B are schematic diagrams that show pipe lines included in the supercritical film deposition apparatus shown in FIG. 1. FIG. 5 is a vertical cross-sectional view that shows a load lock chamber and a transfer chamber included in the supercritical film deposition apparatus shown in FIG. 1. FIG. 6 is a perspective view that shows a partition included in the supercritical film deposition apparatus shown in FIG. 1.

The supercritical film deposition apparatus shown in FIG. 1 includes an autoclave (pressure sustainable container) 40 that includes two reactors (film deposition chambers) 6a and 6b, two load lock chambers 5a and 5b, and a transfer chamber 7. Each of the reactors 6a and 6b, the load lock chambers 5a and 5b, and the transfer chamber 7 has enough strength against high-pressure to perform the supercritical film deposition.

In the supercritical film deposition apparatus shown in FIG. 1, a wafer (substrate) 41, which is imported from outside of the autoclave 40 into the load lock chambers 5a and 5b, is put in a front open unified pod (FOUP) 28 and transferred. The FOUP 28 is a container that stores a plurality of the wafers 41, as shown in FIG. 5. Furthermore, the FOUP 28 allows each of the wafers 41 to be inserted into and ejected from each of a plurality of shelves 28a provided in the autoclave 40 capable of sealing. The wafer 41 stored in the FOUP 28 can be individually inserted and ejected by a robot arm 8, when the FOUP 28 is in the load lock chambers 5a and 5b, as shown in FIG. 5.

In addition, a warm water jacket 29 is provided to cover an outer surface of the autoclave 40 of the supercritical film deposition apparatus shown in FIG. 1. The warm water jacket 29 controls each of the reactors 6a and 6b, the load lock chambers 5a and 5b, and the transfer chamber 7 to have a predetermined temperature. Therefore, the warm water jacket 29 is provided to contact an outer wall of each of the chambers, as shown in FIG. 1, FIG. 2, and FIG. 5. In the supercritical film deposition apparatus shown in FIG. 1, the temperature of each chamber is controlled to exceed the critical temperature by the warm water jacket 29. Furthermore, since the warm water jacket 29 controls the temperature of each chamber, the variation of the deposition (reaction) condition in the film reposition chambers 6a and 6b, can be effectively suppressed, and the temperature variation of an entire of the autoclave 40 with time can be effectively suppressed. Thereby, it is possible to avoid a thermal hysteresis from remaining at the outer wall of the autoclave 40.

The transfer chamber 7 is provided between the reactors 6a and 6b and the load lock chambers 5a and 5b. The transfer chamber 7 is a chamber that transfers the wafer 41 between the reactors 6a and 6b and the load lock chambers 5a and 5b. The transfer chamber 7 includes the robot arm 8 that transfers the wafer 41, as shown in FIG. 1 and FIG. 5. In the supercritical film deposition apparatus shown in FIG. 1, the robot arm 8 transfers the wafer 41 between the reactors 6a and 6b and the load lock chambers 5a and 5b under high-pressure conditions. The transfer chamber 7 further includes feed pipe lines 1a and 1b that supply the supercritical fluid, as shown in FIG. 1.

The film deposition is performed in the reactors (film deposition chambers) 6a and 6b by supplying a deposition source material on the wafer 41 under the supercritical fluid ambient. FIG. 2A is a schematic diagram that shows a state in which the film deposition is performed in the reactor 6b. FIG. 2B is a schematic diagram that shows the state of the reactor 6b when the wafer 41 is replaced. While FIG. 2A and FIG. 2B show one of the reactors, or the reactor 6b, the other of the reactors, or the reactor 6a, has the same configuration.

As shown in FIG. 2A and FIG. 2B, the reactors 6a and 6b include a transfer tunnel (transfer pathway) 42 through which the wafer 41 is transferred from the transfer chamber 7 to the reactors 6a and 6b by the robot arm 8 vice versa. The transfer tunnel 42 is formed to connect the transfer chamber 7 with the reactors 6a and 6b. The width and height of the transfer tunnel 42 are preferably as narrow and low as possible within a range in which the robot arm 8 can transfer the wafer 41. The width and height of the transfer tunnel 42 become narrow and low, and hence, the supercritical fluid flows in one direction without convection. As a result, an outflow (bleed) of the deposition source material and the thermal diffusion from the reactors 6a and 6b to the transfer chamber 7 can be suppressed.

As shown in FIG. 2A and FIG. 2B, the reactors (film deposition chambers) 6a and 6b include a heating table 15 that can heat the wafer 41 to a predetermined temperature for the film deposition (not shown in FIG. 1). Furthermore, the reactors 6a and 6b include a pipe line system 3 that supplies the deposition source material dissolved in the supercritical fluid, and a drain pipe line 4 that ejects the deposition source material dissolved in the supercritical fluid, as shown in FIG. 1 to FIG. 2B. The deposition source material provided through the pipe line system 3 is supplied on the surface of the wafer 41 by ejecting via a shower head 14, as shown in FIG. 2A.

In the supercritical film deposition apparatus shown in FIG. 1, since the transfer chamber 7 includes the feed pipe lines 1a and 1b that supplies the supercritical fluid and the reactors 6a and 6b includes the drain pipe line 4 that ejects the supercritical fluid, the supercritical fluid flows from the transfer chamber 7 to the reactors 6a and 6b. For this reason, the outflow of the deposition source material and the thermal diffusion from the reactors 6a and 6b to the transfer chamber 7 can be effectively suppressed without providing a partition between the transfer chamber 7 and the reactors 6a and 6b. In order to suppress the outflow of the deposition source material and the thermal diffusion from the reactors 6a and 6b to the transfer chamber 7 further effectively, the supercritical fluid, which flows from the transfer chamber 7 to the reactors 6a and 6b, preferably has high purity together with low-temperature ranging from 50 to 80 degree Celsius.

The load lock chambers 5a and 5b import or export the wafer 41 before or after suffering the film deposition. In the supercritical film deposition apparatus shown in FIG. 1, the FOUP 28 storing the wafer 41 before suffering the film deposition is exchanged for the FOUP 28 storing the wafer 41 after suffering the film deposition in the load lock chambers 5a and 5b. The wafer 41 before suffering the film deposition, which is imported from the outside of the autoclave 40, is retained in a condition (supercritical fluid), in which the pressure and temperature are higher than those of the supercritical state, in the load lock chambers 5a and 5b.

As shown in FIG. 1 and FIG. 5, the load lock chambers 5a and 5b include an external gateway 45 and an internal gateway 43. The external gateway 45 imports and exports the wafer 41 from and to the outside of the autoclave 40. The external gateway 45 includes an external partition 45a that isolates the load lock chambers 5a and 5b from the outside thereof. As shown in FIG. 1, when the external partition 45a is closed, the load lock chambers 5a and 5b are insulated from the outside of the autoclave 40. The external partition 45a can move toward the outside of the autoclave 40 so as to open and close. As shown in FIG. 1 and FIG. 5, the external partition 45a has a T-shape in the cross-sectional view, in which an outer diameter of an inner portion of the external partition 45a provided in the load lock chambers 5a and 5b is assumed to fit an inner diameter of the external gateway 45, and an outer diameter of an outer portion directed to the outside of the autoclave 40 is assumed to be larger than the inner diameter of the external gateway 45.

On the other hand, the wafer 41 is transferred to the reactors 6a and 6b through the internal gateway 43 vice versa. As shown in FIG. 1 and FIG. 5, each internal gateway 43 of the two load lock chambers 5a and 5b is connected with the transfer chamber 7. The internal gateway 43 includes partitions 10a and 10b that can open and close, and isolates the load lock chambers 5a and 5b from the outside thereof. As shown in FIG. 1, when the partitions 10a and 10b are closed, the load lock chambers 5a and 5b are insulated from the outside of the internal gateway 43. The partitions 10a and 10b have strength against a large differential pressure (for example, about 20 MPa) that is generated when the external partition 45a is moved so that the load lock chambers 5a and 5b are opened.

The partitions 10a and 10b have a T-shape in the cross-sectional view, in which an outer diameter of an inner portion 43c provided in the load lock chambers 5a and 5b is assumed to fit an inner diameter of the internal gateway 43, and an outer diameter of an outer portion 43d directed to the outside of the load lock chambers 5a and 5b is assumed to be larger than the inner diameter of the internal gateway 43, as shown in FIG. 1, FIG. 5, and FIG. 6. While FIG. 6 shows the partition 10a provided in one of the load lock chambers, or the load lock chamber 5a, the partition 10b provided in the other of the load lock chambers, or the load lock chamber 5b, has the same configuration.

As shown in FIG. 6, the partitions 10a and 10b have a round-shape in the plan-view. Eight pieces of fixtures 11 having a cylindrical shape, which are arranged circularly at regular intervals at the marginal position of the partitions 10a and 10b, through which one end of the fixtures 11 penetrates. As shown in FIG. 5 and FIG. 6, the other end of the fixtures 11 is put in a concave portion provided at a surrounding portion 13 of the internal gateway 43. For this reason, the partitions 10a and 10b are aligned to cover the internal gateway 43, and the closed partitions 10a and 10b are fixed. Furthermore, a seal material 12 including an O-ring and the like is provided at a periphery (outer edge) of the inner portion 43c of the partitions 10a and 10b, as shown in FIG. 6. Thereby, the internal gateway 43 is sealed up by the partitions 10a and 10b.

The partitions 10a and 10b include check valves 9a and 9b, as shown in FIG. 1 and FIG. 6. The check valves 9a and 9b allows the supercritical fluid to flow in one direction from the load lock chambers 5a and 5b to transfer chamber 7, as shown by arrows in FIG. 1. The check valves 9a and 9b are provided at six positions arranged circularly, as shown in FIG. 6. The number of the check valves 9a and 9b provided on the partitions 10a and 10b is not limited, and the number may be one or more.

The partitions 10a and 10b can move toward the transfer chamber 7 provided at the reactors 6a and 6b side, which is against the load lock chambers 5a and 5b. The partitions 10a and 10b move downwardly along a guide rail 46, which is like a pillar and supports moving of the partitions 10a and 10b, after the partitions 10a and 10b is moved toward the transfer chamber 7 side (horizontal direction), as shown by arrows in FIG. 5, when the load lock chambers 5a and 5b are opened for the inside of the autoclave 40. For this reason, when the wafer 41 is inserted to and ejected from the load lock chambers 5a and 5b, the partitions 10a and 10b can avoid contact with the wafer 41 and the robot arm 8.

The load lock chambers 5a and 5b include a pressure control unit that individually controls the pressure therein. In the supercritical film deposition apparatus shown in FIG. 1, the pressure control unit is provided at load lock chamber feed pipe lines 1c and 1d that supply the supercritical fluid to the load lock chambers 5a and 5b, and at load lock chamber drain pipe lines 2a and 2b that eject the supercritical fluid from the load lock chambers 5a and 5b. Furthermore, the check valves 9a and 9b play a role of the pressure control unit.

Subsequently, a pipe line included in the supercritical film deposition apparatus shown in FIG. 1 will be described hereinbelow with reference to FIG. 3A to FIG. 4B.

FIG. 3A is a schematic diagram that shows the feed pipe line 1a for supplying the supercritical fluid to the transfer chamber 7. The feed pipe line 1a supplies the supercritical fluid to the transfer chamber 7, the feed pipe line 1b supplies the supercritical fluid to the transfer chamber 7, and the load lock chamber feed pipe lines 1c and 1d supply the supercritical fluid to the load lock chambers 5a and 5b. The above pipe lines have the same configuration except only for their setting positions. Therefore, the configuration of the feed pipe line 1a, which supplies the supercritical fluid to the transfer chamber 7, is described, on behalf of the above-mentioned pipe lines. That is, the explanations of the feed pipe line 1b that supplies the supercritical fluid to the transfer chamber 7, and of the load lock chamber feed pipe lines 1c and 1d that supply the supercritical fluid to the load lock chambers 5a and 5b, are omitted.

The feed pipe line 1a, which supplies the supercritical fluid to the transfer chamber 7, provides carbon dioxide (CO₂) from a carbon dioxide cylinder (bottle) 20a as the supercritical fluid having predetermined temperature and pressure through a high-pressure valve 16a, carbon dioxide pump 19a as the pressure control unit, and a high-pressure valve 16b provided in a temperature control unit 18a including a heater and the like, as shown in FIG. 3A.

FIG. 3B is a schematic diagram that shows the load lock chamber drain pipe line 2a for ejecting the supercritical fluid from the load lock chamber 5a. The load lock chamber drain pipe line 2a that ejects the supercritical fluid from the load lock chamber 5a, and the load lock chamber drain pipe line 2b that ejects the supercritical fluid from the load lock chamber 5b, have the same configuration except only for their setting positions. Therefore, the configuration of the load lock chamber drain pipe line 2a, which ejects the supercritical fluid from the load lock chamber 5a is described, on behalf of the load lock chamber drain pipe lines. That is, the explanation of the load lock chamber drain pipe line 2b, which ejects the supercritical fluid from the load lock chamber 5a, is omitted.

The load lock drain pipe line 2a, which ejects the supercritical fluid from the load lock chamber 5a, ejects the supercritical fluid ejected having predetermined temperature and pressure through a high-pressure valve 16c provided in a temperature control unit 18b including the heater and the like, and a back-pressure control unit 17a, as shown in FIG. 3B.

FIG. 4A is a schematic diagram that shows the pipe line system 3 for supplying the deposition source material dissolved in the supercritical carbon dioxide.

The pipe line system 3 mixes the supercritical fluid, a reaction reagent, and a material reagent so as to provide as the reaction reagent and the material reagent dissolved in the supercritical carbon dioxide, in which: carbon dioxide is provided from a carbon dioxide cylinder (bottle) 20b as the supercritical fluid having predetermined temperature and pressure through a high-pressure valve 16d, carbon dioxide pump 19b, and a high-pressure valve 16e and a check valve 22a provided in a temperature control unit 18c including the heater and the like; the reaction reagent having a predetermined amount is provided from a reactive gas (oxygen, hydrogen, or the like) cylinder (bottle) 62 through a high-pressure valve 16f, a high-pressure gas mass flow 24, and a check valve 22b; and the material reagent is provided from a liquid reagent (source material) stock container 26 provided in a temperature control unit 18d having predetermined temperature and pressure through high-pressure valves 16g and 16h, a liquid reagent pump 25, and check valve 22c, as shown in FIG. 4A. The pipe line system 3 can supply the supercritical solution that includes the deposition source material and the reaction reagent with arbitrary compositions by operating the various pumps and a mass flow controller, if necessary.

FIG. 4B is a schematic diagram that shows the drain pipe line 4 for ejecting the deposition source material dissolved in the supercritical carbon dioxide.

The drain pipe line 4 collects the deposition source material dissolved in the supercritical carbon dioxide ejected from the reactors 6a and 6b, in which the deposition source material dissolved in the supercritical carbon dioxide is heated by a temperature control unit 18e, and is ejected to a separation and collection container 21 through a back-pressure control unit 17b, as shown in FIG. 4B.

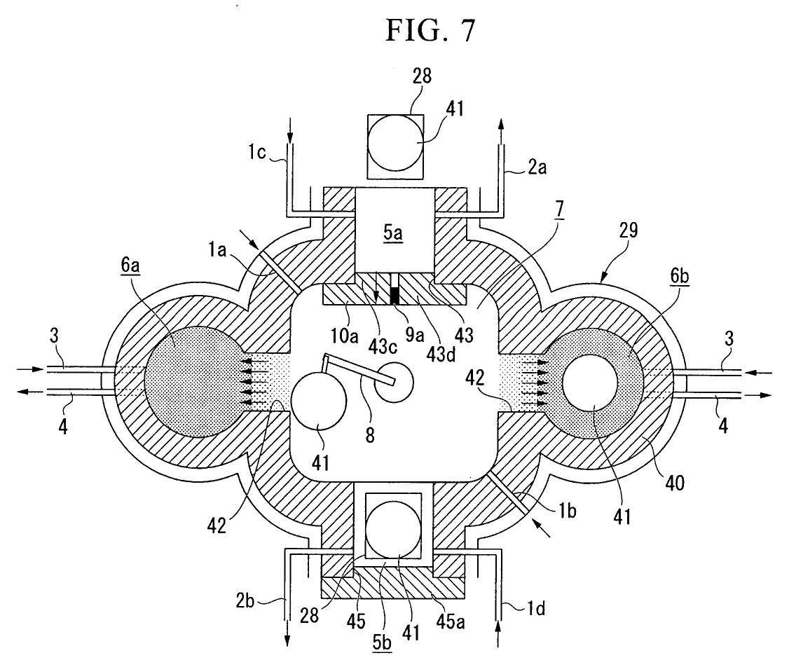

Subsequently, a method of supercritical film deposition, in which a film is deposited on the wafer 41 by using the supercritical film deposition apparatus shown in FIG. 1, will be described hereinbelow with reference to FIG. 7.

First of all, the FOUP 28, which stores a plurality of the wafers 41 before suffering the film deposition, is imported to the load lock chamber 5b when the external partition 45a is opened and the partition 10b is closed. Then, the external partition 45a is closed and sealed up.

Then, carbon dioxide is supplied to the two reactors 6a and 6b through the pipe line system 3, and is compressed. Carbon dioxide is supplied to the transfer chamber 7 through the feed pipe lines 1a and 1b, and is compressed. Carbon dioxide is supplied to one of the two load lock chambers, or the load lock chamber 5b, through the load lock chamber feed pipe line 1d, and is compressed. The temperature of each chamber is controlled by the warm water jacket 29 so as to allow the condition in each chamber to be under the supercritical condition (for example, the pressure of 10 MPa and the temperature of 50 degree Celsius).

Then, the back-pressure control unit 17b provided in the drain pipe line 4 controls the pressures in the reactors 6a and 6b and in the transfer chamber 7, so that the pressures in the reactors 6a and 6b and in the transfer chamber 7 are equalized. Together with this, in order to open the partition 10b easily, the pressure at the reactors 6a and 6b (transfer chamber 7) side of the partition 10b and the pressure in the load lock chamber 5b are controlled by the back-pressure control units 17a and 17b, the load lock chamber feed pipe line 1d, and the check valve 9b, each of which is provided in the drain pipe line 4 and the load lock chamber drain pipe line 2b.

Then, the partition 10b is opened so as to open the internal gateway 43. Thereby, the load lock chamber 5b is opened for the inside of the autoclave 40, as shown in FIG. 7. FIG. 7 is a horizontal cross-sectional view that shows the supercritical film deposition apparatus shown in FIG. 1, in which the partition 10b is opened.

The partition 10b is preferably opened when the pressure at the transfer chamber 7 side of the partition 10b equals that in the load lock chamber 5b.

The partition 10b may be opened when the supercritical fluid flows from the load lock chamber 5b to the transfer chamber 7 through the check valve 9b, in which a setting pressure of the back-pressure control unit 17a of the load lock chamber drain pipe line 2b is controlled to be slightly higher than that of the back-pressure control unit 17b of the drain pipe line 4 (the differential pressure <0.2 MPa), and hence, the pressure in the load lock chamber 5b becomes slightly higher than the pressure at the transfer chamber 7 side of the partition 10b . Since the partition 10b includes the check valve 9b, even when the supercritical fluid flows from the load lock chamber 5b to the transfer chamber 7 through the check valve 9b, the differential pressure between the pressure at the transfer chamber 7 side of the partition 10b and the pressure in the load lock chamber 5b does not increase until interfering with the opening and closing of the partition 10b.

Subsequently, the internal gateway 43 is opened, the robot arm 8 picks up one wafer 41 at a time from the FOUP 28 in the opened load lock chamber 5b, the wafer 41 is transferred to the reactor 6a or the reactor 6b, and then, the wafer 41 is put on the heating table 15 which is heated to the film deposition temperature in advance, as shown in FIG. 7.

After that, the deposition source material and the reaction reagent, which are dissolved in the supercritical carbon dioxide, are simultaneously or continuously supplied from the pipe line system 3 on the wafer 41 put on the heating table 15. Thereby, the film deposition is started. According to the embodiments of the present invention, all of the reactors (film deposition chambers) 6a and 6b, the load lock chamber 5b, and the transfer chamber 7, are assumed to be under the supercritical fluid ambient during the film deposition. Furthermore, since the supercritical fluid having, for example, a temperature of about 50 degree Celsius and a high-purity is supplied from the feed pipe lines 1a and 1b to the transfer chamber 7 and the supercritical fluid is ejected from the reactors 6a and 6b through the drain pipe line 4 during the film deposition, the outflow of the deposition source material from the reactors 6a and 6b and the thermal diffusion from the heating table 15 both to the transfer chamber 7 can be suppressed.

After the predetermined film is deposited on the wafer 41 as described above, the supply of the deposition source material from the pipe line system 3 is stopped. Then, the robot arm 8 exchanges the wafer 41 after suffering the film deposition for the wafer 41 before suffering the film deposition placed in the load lock chamber 5b.

In the embodiments of the present invention, when the supply of the deposition source material from the pipe line system 3 is stopped, it is preferable that the feed pipe lines 1a and 1b and the pipe line system 3 keep supplying the supercritical carbon dioxide with a level of purity, the drain pipe line 4 keeps ejecting the supercritical carbon dioxide, and purging of the reactor 6a and 6b is performed.

Furthermore, in the embodiment of the present invention, when the film is deposited on the wafer 41 in one of the load lock chambers, or the load lock chamber 5b, it is preferable to perform the process described hereinbelow in the other of the load lock chambers, or the load lock chamber 5a.

That is, the pressure in the other of the load lock chambers, or the load lock chamber 5a, is assumed to be an atmospheric pressure, the external partition 45a of the load lock chamber 5a is opened as shown in FIG. 7, and then, the external gateway 45 is opened so that the load lock chamber 5a is opened for the outside of the autoclave 40 (atmosphere opening). During the atmospheric opening, the partition 10a of the load lock chamber 5a adheres to the surrounding portion 13 of the internal gateway 43 due to the differential pressure between the atmosphere and the inside of the autoclave 40. For this reason, pressure sealing between the inside of the autoclave 40 and the load lock chamber 5a can be easily and precisely achieved.

Subsequently, the FOUP 28, which stores a plurality of the wafers 41 before suffering film deposition, is imported to the load lock chamber 5a with atmosphere opening Then, the external partition 45a of the load lock chamber 5a is closed and sealed up After that, the temperature of the load lock chamber 5a is controlled by the warm water jacket 29, carbon dioxide is supplied to the load lock chamber 5a through the load lock chamber feed pipe line 1c, the atmosphere in the load lock chamber 5a is exhausted, and the carbon dioxide is compressed. Thereby, the load lock chamber 5a is assumed to be under the supercritical condition, as is the case with the load lock chamber 5b, the reactors 6a and 6b, and the transfer chamber 7.

Thereafter, when the film deposition on all the wafers 41 in the load lock chamber 5b is completed, the partition 10a is opened and the load lock chamber 5a is opened for the inside of the autoclave 40 as is the case with the partition 10b, and then, the film deposition on the wafer 41 in the load lock chamber 5a is performed, similar to the wafer 41 in the load lock chamber 5b.

Then, the partition 10b of the load lock chamber 5b, to which the wafer 41 after suffering the film deposition is transferred, is closed so as to close the internal gateway 43. At this time, it is preferable that the pressure at the transfer chamber 7 side of the partition 10b and the pressure in the load lock chamber 5b are equalized.

As described above, after the partition 10b of the load lock chamber 5b, the load lock chamber 5b is decompressed to an atmospheric pressure by ejecting carbon dioxide from the load lock chamber 5b, the external partition 45a of the load lock chamber 5b is opened so as to open the external gateway 45, and then, the load lock chamber 5b is opened for the outside of the autoclave 40 (atmosphere opening). After that, the FOUP 28, which stores the wafer 41 after suffering the film deposition, is exported, and then, the FOUP 28, which stores a plurality of the wafers 41 before suffering the film deposition, is imported.

Hereinafter, as is the case described above, the external partition 45a of the one of the load lock chambers 5a and 5b is opened so as to open the external gateway 45, the load lock chamber 5b is opened for the outside of the autoclave 40 (atmosphere opening), the partition 10b of the other of the load lock chambers 5a and 5b is opened so as to open the internal gateway 43, and then, the load lock chamber 5b is opened for the inside of the autoclave 40. After that, exchanging the wafer 41 after suffering the film deposition for the wafer 41 before suffering the film deposition in one of the load lock chambers, and the film deposition on the wafer 41 imported to the other of the load lock chambers, are simultaneously performed. Thereby, the film is deposited on all the wafers 41 before suffering the film deposition.

In the supercritical film deposition apparatus shown in FIG. 1, the internal gateway 43 of the load lock chambers 5a and 5b includes the partitions 10a and 10b capable of opening and closing so as to isolate the load lock chambers 5a and 5b from the outside of the internal gateway 43. Since the load lock chamber feed pipe lines 1c and 1d, the load lock chamber drain pipe lines 2a and 2b, and the check valves 9a and 9b include the pressure control unit in the load lock chambers 5a and 5b, the pressure in the load lock chambers 5a and 5b can be controlled by these pressure control units. Thereby, the partitions 10a and 10b can be easily opened and closed.

For example, the pressure at the transfer chamber 7 side of the partitions 10a and 10b and the pressure in the load lock chambers 5a and 5b are controlled to be the same. Alternately the pressure in the load lock chambers 5a and 5b is controlled to flow the supercritical fluid from the load lock chamber 5b to the transfer chamber 7 through the check valve 9a and 9b. Thereby, the partitions 10a and 10b can be easily opened and closed. For this reason, an excess load is not easily subjected to the partitions 10a and 10b, the guide rail 46 that supports the partitions 10a and 10b, the fixture 11 that opens and closes the partitions 10a and 10b, and the like. Therefore, durability of the supercritical film deposition apparatus can be enhanced.

The supercritical film deposition apparatus shown in FIG. 1 further includes the pressure control unit that controls the pressure in the load lock chambers 5a and 5b, in addition to the partitions 10a and 10b. Therefore, even when the reactors 6a and 6b and the transfer chamber 7 are in the high-pressure condition, while only the load lock chambers 5a and 5b are assumed to be under the atmospheric pressure condition by closing the partitions 10a and 10b, the wafer 41 in the load lock chambers 5a and 5b can be imported and exported.

Therefore, according to the supercritical film deposition apparatus shown in FIG. 1, there is no necessity to take a time for each of pressurization of the reactors 6a and 6b, decompression, and heating the wafer 41, which are limiting factors in the supercritical film deposition. For this reason, the film deposition on the wafer 41 can be performed by sequentially exchanging the wafer 41 after suffering the film deposition in the reactors 6a and 6b. Therefore, according to the supercritical film deposition apparatus shown in FIG. 1, a throughput of the method of supercritical film deposition can be drastically improved.

Alternately, according to the supercritical film deposition apparatus shown in FIG. 1, there is no necessity to allow the reactors 6a and 6b to open for atmosphere whenever the film deposition on one wafer 41 is completed. For this reason, it is possible to remarkably reduce the number of occasions at which the reactors 6a and 6b are exposed to contaminants in air, as compared to the case in which atmosphere opening is carried out whenever the film deposition on one wafer 41 is completed. Accordingly, a high-quality film can be obtained while maintaining reproducibility.

In the supercritical film deposition apparatus shown in FIG. 1, the transfer chamber 7 is provided between the reactors 6a and 6b and the load lock chambers 5a and 5b, the feed pipe lines 1a and 1b, which supply the supercritical fluid, is provided in the transfer chamber 7, the drain pipe line 4, which ejects the supercritical fluid, is provided in the reactors 6a and 6b, the supercritical fluid flows from the transfer chamber 7 to the reactors 6a and 6b. As a result, the diffusion of the heat and the deposition source material from the reactors 6a and 6b to the transfer chamber 7 can be effectively suppressed. Accordingly, the variation of the deposition condition in the reactors 6a and 6b can be effectively suppressed, and the temperature variation of the entire of the supercritical film deposition apparatus with time can be further effectively suppressed.

According to the supercritical film deposition apparatus shown in FIG. 1, the internal gateway 43 of the two load lock chambers 5a and 5b is connected with the transfer chamber 7. When the external gateway 45 of one of the load lock chambers is opened, the internal gateway 43 of the other of the load lock chambers is opened. Therefore, exchanging the wafer 41 after suffering the film deposition for the wafer 41 before suffering the film deposition in one of the load lock chambers, and the film deposition on the wafer 41 in the other of the load lock chambers, can be simultaneously performed. In this case, a time except for the film deposition is minimized (for example, pressurization to exceed the critical pressure in the autoclave 40, decompression to an atmospheric pressure in the load lock chambers 5a and 5b, heating to a film deposition temperature in the autoclave 40), so as to enable effective performance of the film deposition on the wafer 41 sequentially.

In addition, in the supercritical film deposition apparatus shown in FIG. 1, since the pressure control unit, which individually controls the pressures in the load lock chambers 5a and 5b, is provided, when exchanging the wafer 41 after suffering the film deposition for the wafer 41 before suffering the film deposition in one of the load lock chambers, and the film deposition on the wafer 41 in the other of the load lock chambers, are simultaneously performed, the pressures in the load lock chambers 5a and 5b can be easily and individually controlled. Therefore, the film deposition can be safely and constantly performed using the load lock system.

Furthermore, in the supercritical film deposition apparatus shown in FIG. 1, since the pressure control unit controls the pressure in the load lock chambers 5a and 5b, the pressure at the transfer chamber 7 side of the partitions 10a and 10b and the pressure in the load lock chambers 5a and 5b are controlled to be the same. Alternately the pressure in the load lock chambers 5a and 5b is controlled so that the supercritical fluid flows from the load lock chamber 5b to the transfer chamber 7 through the check valve 9a and 9b. Thereby, the partitions 10a and 10b can be easily opened and closed.

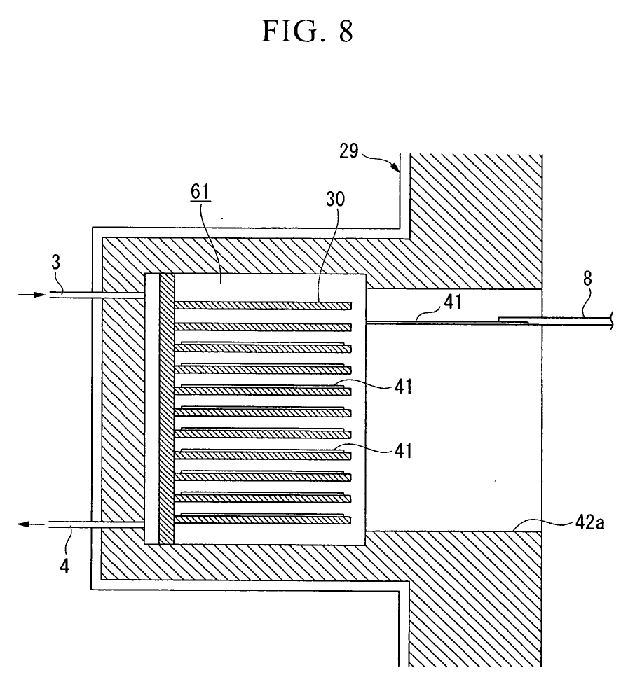

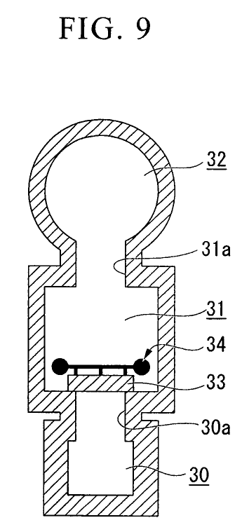

Subsequently, a second embodiment of a supercritical film deposition apparatus and a method of supercritical film deposition of the present invention will be described in detail hereinbelow with reference to the drawings. FIG. 8 is a vertical cross-sectional view that shows another example of the supercritical film deposition apparatus of the present invention. In the supercritical film deposition apparatus according to the second embodiment, although the reactor (film deposition chamber) is different from the supercritical film deposition apparatus shown in FIG. 1, the other components are the same. Therefore, the explanation of the same configuration as the supercritical film deposition apparatus shown in FIG. 1 is omitted or simplified for the supercritical film deposition apparatus of the second embodiment shown in FIG. 8.

The reactors 6a and 6b included in the supercritical film deposition apparatus shown in FIG. 1 is the so-called piece-to-piece system. On the other hand, a reactor 61 included in the supercritical film deposition apparatus shown in FIG. 8 is a batch system that can simultaneously deposit films on a plurality of the wafers 41. As shown in FIG. 8, the batch type reactor 61 includes a plurality of heating tables 30 which are separated from each other and are arranged along the vertical direction (for example, 25 heating tables are shown). In order to suppress undesirable deposition on a back surface of the heating table 30, a thermal barrier layer made of a thermal insulator may be provided on the back surface of the heating table 30. Each wafer 41 is put on a heat zone of each heating table 30, and the film is deposited on the wafer 41.

Subsequently, the method of supercritical film deposition, which deposits films on the wafer 41 using the supercritical film deposition apparatus shown in FIG. 8, will be described hereinbelow.

When the supercritical film deposition apparatus shown in FIG. 8 is used, as is the case with the supercritical film deposition apparatus shown in FIG. 1, the load lock chamber 5b is opened, the robot arm 8 picks up wafer 41 one by one from the FOUP 28 in the load lock chamber 5b, the wafer 41 is transferred to the reactor 61, the wafer 41 is put on the heating table 30 which is heated to the film deposition temperature in advance, and then, the film is deposited on the wafer 41. As is different from the case with the supercritical film deposition apparatus shown in FIG. 1, the films are simultaneously deposited on a plurality of the wafers 41 by using the supercritical film deposition apparatus shown in FIGS. 8. The robot arm 8 exchanges the wafer 41 after suffering the film deposition for the wafer 41 before suffering the film deposition in the load lock chamber 5b.

Since the supercritical film deposition apparatus including the batch type reactor 61 can simultaneously deposit the films on a plurality of the wafers 41, it is possible to enhance the throughput rather than that of the supercritical film deposition apparatus including the piece-to-piece type reactors 6a and 6b shown in FIG. 1. However, in light of the uniformity in a whole wafer or in a lot, the piece-to-piece type reactors 6a and 6b are superior to the batch type reactor 61. Accordingly, it is necessary only to decide which type of the reactors, the piece-to-piece type reactors 6a and 6b or the batch type reactor 61, is employed by considering the characteristic and throughput desired to the film.

In the supercritical film deposition apparatus shown in FIG. 8, the internal gateway 43 of the load lock chambers 5a and 5b includes the partitions 10a and 10b capable of opening and closing so as to isolate the load lock chamber 5a and 5b from the outside of the internal gateway 43. Since the load lock chamber feed pipe lines 1c and 1d, the load lock chamber drain pipe lines 2a and 2b, and the check valves 9a and 9b include the pressure control unit in the load lock chambers 5a and 5b, the pressure in the load lock chambers 5a and 5b can be controlled by these pressure control units. Thereby, the partitions 10a and 10b can be easily opened and closed.

The present invention is not limited to the above embodiments. For example, the chamber number of the reactor and the load lock chamber is not limited two. The chamber number may be one, or three or more, and the number can be determined by consideration of productivity, the film deposition condition, and the like. It is preferable that all of the load lock chamber feed pipe line, the load lock chamber drain pipe line, and the check valve, have the pressure control unit, and are interacted with each other, since the pressure in the load lock chamber can be easily and precisely controlled. However, if the pressure in the load lock chamber can be controlled, any configuration may be employed. For example, only the load lock chamber feed pipe line or a set of the load lock chamber feed pipe line and the check valve may be employed.

According to the supercritical film deposition apparatus of the present invention, the load lock chamber includes the pressure control unit that controls the pressure therein, the external gateway that imports and exports the wafer from and to the outside of the autoclave, the internal gateway that transfers the wafer to and from the reactor, wherein the internal gateway includes the partition that enables to open and close so as to isolate the load lock chamber from the outside of the internal gateway. Thereby, the pressure control unit controls the pressure in the load lock chamber so as to enable to easily open and close the partition. As a result, the partition can be easily opened and closed. For this reason, the excess load is not easily subjected to the partition, the components that support, open and close the partition. Therefore, durability of the partition, the components that support, open and close the partition can be enhanced.

According to the supercritical film deposition apparatus of the present invention, the transfer chamber is provided between the reactor and the load lock chamber, the feed pipe line, which supplies the supercritical fluid, is provided in the transfer chamber, the drain pipe line, which ejects the supercritical fluid, is provided in the reactor. When the supercritical fluid flows from the transfer chamber to the reactor, the diffusion of the heat and the deposition source material from the reactor to the transfer chamber can be effectively suppressed. Therefore, the temperature variation of the entire apparatus with time can be suppressed. As a result, the degradation and damage of each component by the temperature variation with time can be prevented.

According to the method of supercritical film deposition of the present invention, the film deposition on the substrate is performed by using the supercritical film deposition apparatus of the present invention. In the method of supercritical film deposition, since the pressure control unit controls the pressure in the load lock chamber, the partition can be easily opened and closed by controlling the pressure in the load lock chamber.

It is apparent that the present invention is not limited to the above embodiments, but may be modified and changed without departing from the scope and spirit of the invention.

Alternately, although the invention has been described above in connection with several preferred embodiments thereof, it will be appreciated by those skilled in the art in that those embodiments are provided solely for illustrating the invention, and should not be relied upon to construe the appended claims in a limiting sense.

What is claimed is:

1. A supercritical film deposition apparatus for depositing a film on a substrate under a supercritical fluid ambient by supplying a deposition source material, comprising:
an autoclave that includes a reactor;
a load lock chamber that is provided in said autoclave, said substrates before and after suffering depositing said film being transferred;
a pressure control unit that is provided in said load lock chamber to control a pressure in said load lock chamber;
an external gateway that is provided in said load lock chamber to transfer said substrate from and to outside of said autoclave;
an internal gateway that is provided in said load lock chamber to transfer said substrate from and to said reactor; and
a partition capable of opening and closing so as to isolate said load lock chamber from outside of said internal gateway.

2. The supercritical film deposition apparatus as recited in claim 1, wherein:
at least one part of an outer boundary of said partition is larger than an inner boundary of said internal gateway;
said partition moves toward said reactor; and
said partition includes a check valve that allows a supercritical fluid to flow in one direction from said load lock chamber to said reactor.

3. The supercritical film deposition apparatus as recited in claim 2, wherein
said pressure control unit is provided at a load lock chamber feed pipe line that supplies said supercritical fluid to said load lock chamber, ad is provided at a load lock chamber drain pipe line that ejects said supercritical fluid from said load lock chamber.

4. The supercritical film deposition apparatus as recited in claim 1, further comprising
a warm water jacket that is provided on an outer wall of said autoclave.

5. The supercritical film deposition apparatus as recited in claim 2, further comprising
a transfer chamber that is provided between said reactor and said load lock chambers
wherein:
said transfer chamber includes a feed pipe line that supplies said supercritical fluid thereto;
said reactor includes a drain pipe line that ejects said supercritical fluid therefrom; and
said supercritical fluid flows from said transfer chamber to said reactor.

6. The supercritical film deposition apparatus as recited in claim 5, further comprising
a plurality of said load lock chambers, each of which includes said internal gateway,
wherein
each of said plurality of said internal gateway connects with said transfer chamber.

7. The supercritical film deposition apparatus as recited in claim 6, wherein
said pressure control unit individually controls said pressure in each of said plurality of said load lock chambers.

8. The supercritical film deposition apparatus as recited in claim 1, wherein
said pressure in said load lock chamber is controlled to equal to or exceed a pressure at a reactor side of said partition of said load lock chamber, when said partition is opened and closed.
